(19) United States
(12) Patent Application Publication
(10) Pub. No.: US 2005/0141578 A1
(43) Pub. Date: Jun. 30, 2005

(54) Laser diode structure with blocking layer

(76) Inventors: Benoit Reid, Orleans (CA); Arnaud Christian Fily, Zurich (CH); Norbert Lichtenstein, Adliswil (CH); D. Gordon Knight, London (CA)

Correspondence Address: HOLLAND & HART, LLP, 555 17TH STREET, SUITE 3200, DENVER, CO, 80201, US

(21) Appl. No.: 10/871,895

(22) Filed: Jun. 18, 2004

Related U.S. Application Data
(60) Provisional application No. 60/479,868, filed on Jun. 20, 2003.

(51) Int. Cl. H01S 5/00

(52) U.S. Cl. 372/45; 372/46

(57) ABSTRACT

The present invention provides a self-aligned laser structure that can be fabricated on a p-substrate and provides a means for limiting the leakage current thereby improving the overall efficiency of the structure. The waveguide laser structure comprises a first series of layers deposited in sequence upon a p-InP, p-GaAs or p-GaN substrate or other form of p-substrate, wherein these layers form the p-clad layer. An active layer is subsequently deposited upon this first series of layers. A blocking layer of insulating or semi-insulating material is deposited upon the active layer, wherein this blocking layer has a trench formed therein, wherein this semi-insulating layer or layers are epitaxially deposited. The blocking layer provides a means for limiting current flow therethrough, thereby reducing leakage current. Upon the blocking layer are deposited a second series of layers completing the laser structure, wherein this second series of layers form the n-clad layer. Since the n-clad layer contains more than one material, the structure provides lateral waveguiding. Upon the completion of the deposition of all of the layers, a positive electrode is formed on the bottom surface of the first series of layers and a negative electrode is formed on the top of the second series of layers.

This application claims the benefit of U.S. Patent Application Ser. No. 60/479,868 filed Jun. 20, 2003.

### FIELD OF THE INVENTION

The present invention pertains to the field of semiconductor lasers and more particularly to semiconductor lasers fabricated using p-substrate.

### BACKGROUND

The ridge waveguide laser is a semiconductor light-emitting device that includes a ridge-shaped layer on a semiconductor wafer. It is one of the simplest and most reliable laser devices available today. One such laser and its fabrication process has been described in an article “High Power Ridge-Waveguide AlGaAs GRINSCH Laser Diode” by C. Harder et al. (published in Electronics Letters, Sep. 25, 1986, Vol. 22, No. 20, pp. 1081-1082).

In the past, most of the efforts made in designing semiconductor lasers were directed to GaAs system devices operating at a wavelength of about 0.8 μm. However more recently and particularly for communication applications, lasers emitting beams of a longer wavelength (in the order of 1.4 μm) have become the major requirement since they better match the transmission characteristics of the fiber-optical links used. Presently the only material commercially available for lasers of these wavelengths is based on InP material system. An extensive survey on such structures, including ridge-waveguide lasers, and their performance is given in Chapter 5 of a book entitled “Long Wavelength Semiconductor Lasers” by G. P. Agrawal and N. K. Dutta (Van Nostrand Reinhold Company, N.Y.).

Semiconductor lasers play a key role in high data rate communication systems. Their speed and performance define the capability of the systems in which they work. Any advancement in their specification and reduction in their cost can provide significant improvement in the overall capability of the final communication systems. Particular areas where improvement is needed are for example, lower power dissipation, lower cost, higher temperature operation and greater functionality. The p-substrate design addresses the functionality requirement by providing a high quality laser, that because of the common anode, could be integrated with other electronics in a single package.

A semiconductor laser comprises a structure of semiconductor layers excited by an external current source. With a suitable design, the light emitted can be controlled by the source current. The design of the semiconductor structure is fundamental to the overall performance of the laser.

Of particular interest are semiconductor laser structures based on a p-doped InP substrate, which have the capability of being part of large opto-electronic integrated circuits. FIG. 1 shows a ridge waveguide semiconductor structure based on a p-InP substrate. This structure, however, suffers from excessive lateral leakage current due to the high electron mobility in InP based materials, significantly degrading the threshold current and the slope efficiency, and rendering the lasers inefficient and less attractive for real applications. The need to reduce this leakage current, a particular problem on p-substrate in the active region is an important requirement. By reducing this leakage current, the overall efficiency of the laser can be improved, less cooling may be required and a higher output signal can be achieved.

Attempts have been made to solve this problem. A buried heterostructure laser on a p-substrate is described by Takemi et al., Journal of Crystal Growth 180 (1997) pp 1-8, and is shown in FIG. 2. Buried heterostructures solve some aspects of the leakage current problem, but require multiple process steps which etch through the active region and regrow the current blocking layers. These processes may introduce nonradiative recombination centres close to the active region, degrading performance and the reliability of the device. Also, high doping levels close to the area of high optical intensity can increase the optical losses, making such devices less attractive for high power applications. Moreover, in a buried heterostructure, it is difficult to optimise the growth of the blocking layers to minimise potential leakage current-paths. The reduction in the number of steps to fabricate each device can enable higher overall chip yield and potentially lower manufacturing costs.

Channel guide lasers on p-substrate have also been demonstrated. Such an implementation is described by Sin et al., J. Applied Physics 72 (1992), p.3212. FIG. 3 shows an example of the semiconductor structure. The growth of the active region, however which is a critical part of the laser, happens in an overgrowth step, which might raise questions about its quality.

Ridge-waveguide lasers on p-doped substrate suffer from excessive lateral current leakage because of the high electron mobility in InP based material. This excessive lateral leakage current can degrade the threshold current and the slope efficiency rendering the lasers inefficient and less attractive for real applications. For example, threshold current can be 3-4 times higher, and slope efficiency 3-4 times lower on p-substrate lasers when compared with their counterparts on n-substrate. Yet p-substrate lasers are useful from a device integration perspective, because a common anode can drive various devices.

By combining the advantages of the comparatively simple processes of ridge waveguide lasers and buried heterostructure lasers, improved control of the leakage current can be achieved. FIG. 4 shows such a semiconductor structure. However, one potential problem with this structure on p-substrate is the lateral leakage that can occur below the p-blocking layer. With regard to FIG. 4, the leakage current occurs in layer 41, which is a n-doped layer. Below the trench, electrons would tend to go sideways because they are no longer confined. The movement of the electrons depends on their mobility and as such the higher the mobility the further they will travel. The movement of electrons in n-doped material is much greater than the movement of holes in a p-doped material because electron mobility is more than 10 times greater than hole mobility. Current that progresses sideways is essentially lost thereby decreasing the overall efficiency of the laser. One option would be to remove layer 41, however this would result in the elimination of a reverse bias pn-junction and as such the current would not be confined to the trench, consequently resulting in a poor performing laser.

Semiconductor lasers, because of their widespread use, are typically required to be inexpensive and efficient, with a minimum requirement for external optical power in addition to a low level of heat dissipation. Design changes have been introduced aimed at meeting these requirements, however a problem relating to lateral current leakage remains, together with its other potential associated inefficiencies. This leakage current can be caused by a lack of containment at the edges of the active region, thereby allowing current to flow away from the area of interest. Techniques have been proposed to solve this problem, but have been unable to meet the requirements of ease of fabrication and the control of the leakage current. Buried heterostructures solve some aspects of the leakage current problem, but require multiple process steps and can produce nonradiative recombination centres which can degrade performance. Channel guide lasers on p-substrate can use an overgrowth on the active region, which being a critical part of the laser can cause quality problems and limit optimisation of a design. The use of a p-blocking layer is limited by the lateral leakage that can occur below this layer.

Therefore there is a need for a new design of a semiconductor laser on p-substrate.

This background information is provided for the purpose of making known information believed by the applicant to be of possible relevance to the present invention. No admission is necessarily intended, nor should be construed, that any of the preceeding information constitutes prior art against the present invention.

### SUMMARY OF THE INVENTION

An object of the present invention is to provide a laser diode structure with blocking layer. In accordance with one aspect of the present invention, there is provided a semiconductor laser structure, based on p-substrate materials, said structure including a plurality of layers, each layer including one or more sublayers, said structure comprising: a first layer forming a p-clad layer, said first layer having a bottom surface; a second layer being an active layer deposited on the first layer; a third layer being a blocking layer formed from an insulating or semi-insulating material, said blocking layer including two parts aligned with a gap therebetween, said gap and said blocking layer having dimensions selected to meet a desired response of the semiconductor laser structure, said blocking layer deposited on the active layer; and a fourth layer forming a n-clad layer, said fourth layer having a top surface, said fourth layer deposited on the third layer; wherein a negative electrode is formed on the top surface and a positive electrode is formed of the bottom surface.

In accordance with another aspect of the present invention, there is provided a semiconductor laser structure, based on p-substrate materials, said structure including a plurality of layers, each layer including one or more sublayers, said structure comprising: a first layer, said first layer comprising a p-InP substrate, said first layer having a bottom surface; a second layer deposited on the first layer, said second layer being an active layer; a third layer deposited on the second layer, said third layer being a blocking layer comprising an insulating or semi-insulating material, said third layer including two parts, aligned with a gap therebetween, said gap having dimensions selected to meet a required specific response of the structure; a fourth layer deposited on the third layer, said fourth layer comprising a n-InGaAsP layer; and a fifth layer deposited on the fourth layer, said fifth layer being a cladding layer comprising a n-InP layer and said fifth layer having a top surface; wherein a negative electrode is formed on the top surface and a positive electrode is formed of the bottom surface.

It is an object of the present invention to provide a semiconductor laser fabricated on a p-substrate having improved lateral current performance compared to the ridge waveguide laser, and a simpler fabrication process than a laser with a buried heterostructure.

The disclosed semiconductor laser involves the introduction of blocking layers onto the active region of the laser, thereby limiting the leakage current path and improving the efficiency and output power of the laser.

The implementation of these blocking layers can be achieved by the deposition of an insulating or semi-insulating material for example an iron-doped indium phosphide layer on top of the active region.

The manufacturing method can be eased by the use of iron-doped indium phosphide and may reduce the cost and time to produce the self-aligned laser structure when compared to a buried heterostructure.

### BRIEF DESCRIPTION OF THE FIGURES

FIG. 1 illustrates a cross-section of a ridge-waveguide laser structure on p-InP substrate, showing the problems associated with lateral current leakage.

FIG. 2 illustrates a cross-section of a buried heterostructure laser on a p-substrate according to Takemi et al.

FIG. 3 illustrates a cross section of a channel guide laser on a p-substrate according to Sin et al.

FIG. 4 illustrates a laser with a self-aligned structure using p-type blocking layers indicating the potential lateral current leakage associated therewith.

FIG. 5 illustrates a cross-section of a self-aligned semiconductor laser structure with blocking layers according to one embodiment of the present invention.

FIG. 6 illustrates a cross-section of a self-aligned semiconductor laser structure with blocking layers fabricated using InP according to one embodiment of the present invention.

FIG. 7A is a graphical representation of the optical signal showing contour lines denoting the magnitude of the optical signal level at locations within the structure, according to one embodiment of the present invention.

FIG. 7B is a graphical representation of the values of the electrical current with respect to locations within the structure according to one embodiment of the present invention.

FIGS. 8A to 8D illustrate the layers and fabrication steps of a distributed feedback laser according to one embodiment of the present invention.

FIGS. 9A to 9E illustrate the layers and fabrication steps of a second distributed feedback laser according to another embodiment of the present invention.

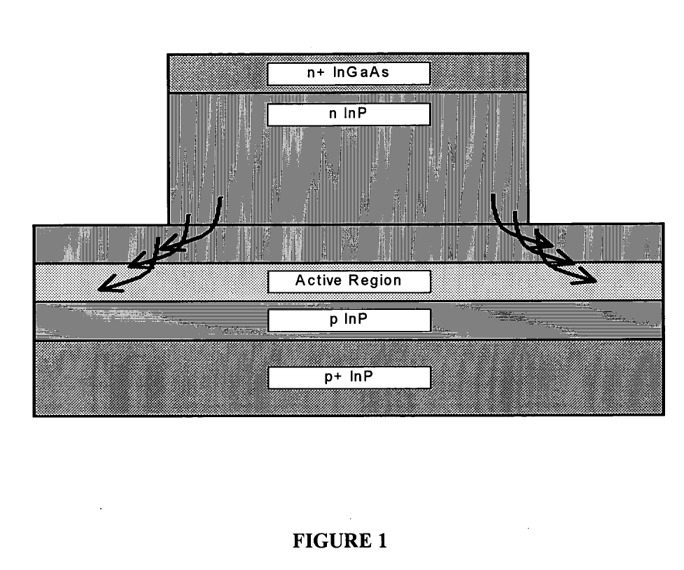

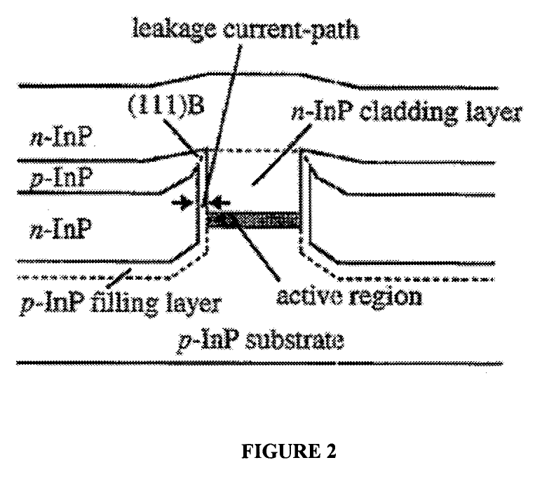

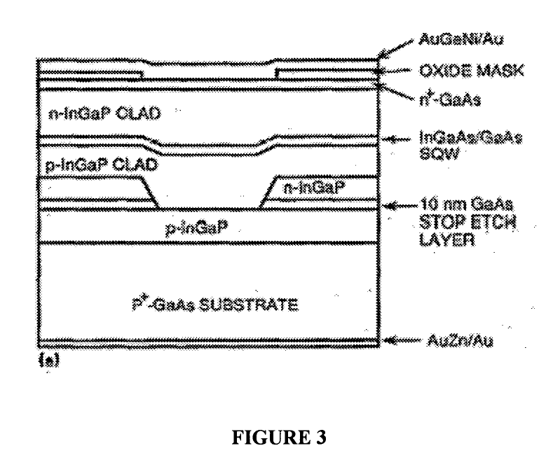

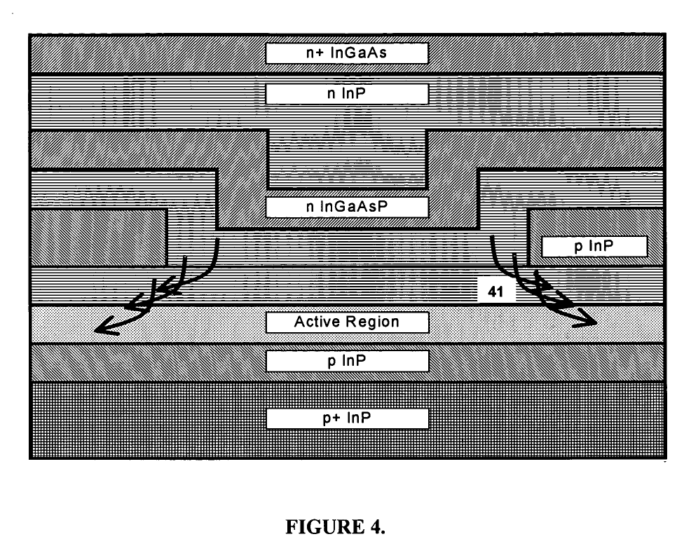

### DETAILED DESCRIPTION OF THE INVENTION

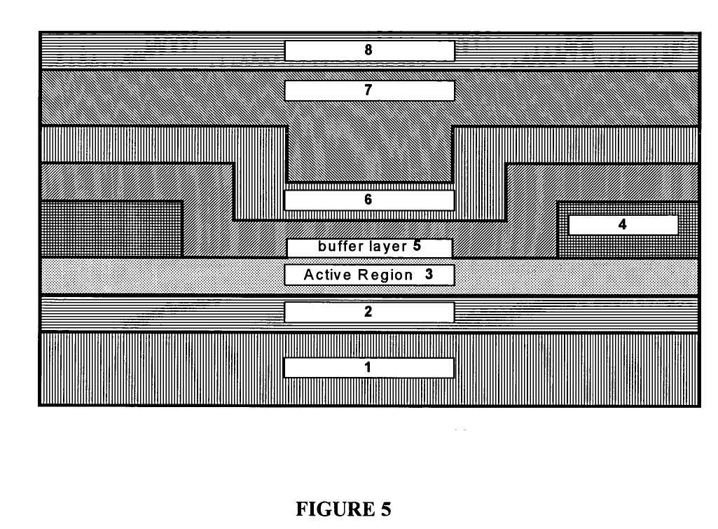

The present invention provides a self-aligned laser structure that can be fabricated on a p-substrate and provides a means for limiting the leakage current thereby improving the overall efficiency of the structure. The waveguide laser structure comprises a first series of layers deposited in sequence upon a p-InP, p-GaAs or p-GaN substrate or other form of p-substrate, wherein these layers form the p-clad layer. An active layer is subsequently deposited upon this first series of layers. A blocking layer of insulating or semi-insulating material is deposited upon the active layer, wherein this blocking layer has a trench formed therein, wherein this semi-insulating layer or layers are epitaxially deposited. A semi insulating material forming the blocking layer is defined as a material that inhibits electron or hole currents by trapping carriers. The blocking layer provides a means for limiting current flow therethrough, thereby reducing leakage current. Upon the blocking layer are deposited a second series of layers completing the laser structure, wherein this second series of layers form the n-clad layer. Since the n-clad layer contains more than one material, the structure provides lateral waveguiding. For example, the trench layer 6 in FIG. 5, which has the highest index of refraction in the structure is dropped closer to the active region and influences the vertical waveguiding by increasing the local effective index. Layer 6 is made of materials with a higher index of refraction than the blocking layers, which can provide the necessary index step for lateral waveguiding. The position of the trench within the blocking layer defines simultaneously the lateral position of the optical mode and the current injection path into the optical mode, thus this structure can be defined as self-aligned. Upon the completion of the deposition of all of the layers, a positive electrode is formed on the bottom surface of the first series of layers and a negative electrode is formed on the top of the second series of layers.

The structure, according to the present invention, provides a means for reducing the number of layer growth sessions required for the fabrication of the waveguide laser when compared to a buried heterostructure laser. Furthermore the structure provides a means for controlling the leakage current through the deposition of the blocking layer on top of the active layer, wherein this blocking layers has a trench defined therein.

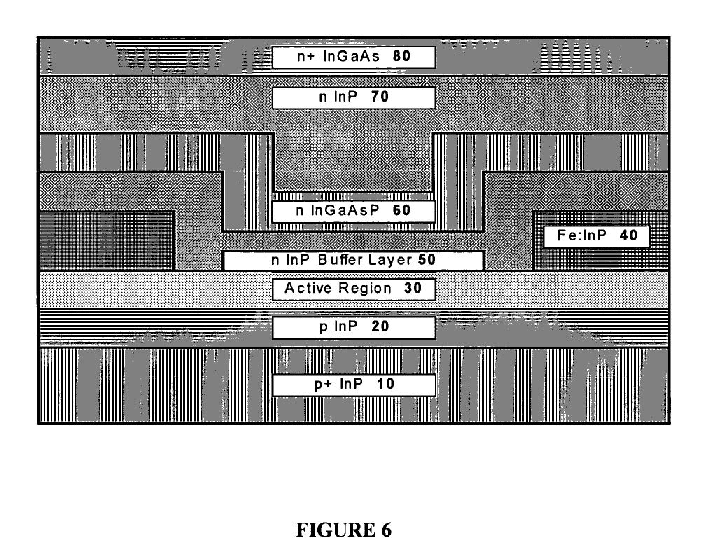

Having regard to FIG. 5, a schematic of a waveguide semiconductor laser structure according to one embodiment of the present invention is illustrated. FIG. 6 illustrates another embodiment of the present invention wherein an InP p-substrate is used for the design of the structure and the layers that are deposited thereon in order to provide the functionality to the waveguide semiconductor laser structure would be determined based on this substrate material, as would be known to a worker skilled in the art. For example, a GaAs p-substrate or GaN p-substrate may additionally be used and the compositions of the layers would be modified accordingly as would be readily understood by a skilled technician. A device based on GaAs works at shorter wavelengths when compared with InP based device, for example a GaAs device operates at approximately 980 μm. A device based on GaN works at even shorter wavelengths when compared with a GaAs based device, and a GaN based structure is typically used in the field of storage devices, for example DVDs. The waveguide semiconductor laser structure can be divided into three sections deposited in sequence, namely a first series of layers forming a p-clad with an active layer deposited on top thereof, a blocking layer and a second series of layers forming a n-clad, wherein positive and negative electrodes are formed on the p-clad and n-clad layers, respectively.

There are many materials and material compositions of the layers that can be used to form the waveguide semiconductor laser, wherein this would depend on the targeted application, for example the desired wavelength, trench width, optical mode dimension, high power optimisation and optimisation for a directly modulated laser. For example, alloys from which the layers can be formed that are suitable for an InP based laser are InGaAsP and InAlGaAs among others as would be readily understood. Additionally, alloys that are suitable for a GaAs based laser can include AlGaAs and InGaAsP, for example. Other types of alloys may also be used as would be known to a worker skilled in the art.

It would be readily understood by a worker skilled in the art that while FIG. 5 illustrates a particular number of layers being deposited on the p-substrate, each of these identified layers can be formed by a plurality of layers depending on the targeted application or optionally there may be fewer layers within the structure.

First Series of Layers

With further reference to FIG. 5, the first series of layers provides the p-clad layers 1 and 2, wherein the base layer 1 provides a suitable interface for the p-side electrode. Deposited on top of this first series of layers is an active layer 3.

In one embodiment and with reference to FIG. 6, the waveguide semiconductor laser is based on an InP substrate. In this case the first series of layers of the waveguide semiconductor laser are formed by depositing a base layer of p+InP 10, which provides a suitable interface for the p-side electrode, onto which layers of p InP 20 are deposited sequentially. Subsequently an active layer 30 formed from a material compatible with InP, for example as InGaAsP or InAlGaAs alloys is deposited on top of this first series of layers.

In an alternate embodiment, the waveguide semiconductor laser can be based on a GaAs substrate wherein the first series of layers can include a series of layers of a p-conductivity type which are formed from material having a composition compatible with that of the GaAs substrate. Upon this first series of layers an appropriate active layer would be deposited.

In general, the waveguide semiconductor laser may not be based on InP or GaAs. In this case the first series of layers comprises a set of layers of p-conductivity, the first of which is a suitable interface for the positive electrode. Deposited upon this first series of layers would be an active layer which can be a p- or n-conductivity type of material. Optionally, the active layer can be undoped.

Blocking Layer

With further reference to FIG. 5, the blocking layer 4 is a layer of material deposited within the semiconductor laser structure on top of the active layer 3. This blocking layer limits current flow within the blocked area, thereby providing a means for controlling current flow within chosen areas. The blocking layer according to the present invention is formed from an insulating or semi-insulating material wherein this type of material prevents or limits the flow of current therethrough, thus providing a means for controlling the flow of current within the waveguide semiconductor laser structure.

The blocking layer comprises two aligned portions having a trench therebetween as illustrated in FIG. 5. These two aligned portions of the blocking layer and the overgrowth material in the trench, as illustrated by layer 6 of FIG. 5, provide the lateral optical guiding. During fabrication, the blocking layer can be deposited as a complete layer of material on top of the active layer. Subsequent etching of this layer enables the creation of the trench thereby enabling the creation of a trench having a desired depth and thickness for enabling the control of both the optical mode and the flow of current. This technique can be advantageous over the deposition of material on opposite sides of a defined mesa, or ridge, as in a buried heterostructure, since control of the etching procedure can be provided with more precision as opposed to the deposition procedure on a non-planar surface. In addition this procedure can provide a means for resulting in a self-aligned waveguide layer.

The semi-insulating material can have an additional benefit in that it may be deposited directly onto the active layer, allowing for blockage of the current over the active region. By fully blocking the sides of the active layer, almost all current can be controlled.

In one embodiment, a further advantage of the invention is that it allows for independent adjustment of current and optical confinement, enabling lasers to be designed for specific requirements. This can be provided by adjusting the size and shape of these blocking layers and the size and shape of the trench etched into this blocking layer, thereby giving a wide range of performance parameters. For example, parameters that can be adjusted are the width of the trench that is etched into the blocking layer, the thickness of the blocking layer and the contour of the blocking layer.

In one embodiment of the present invention, the insulating or semi-insulating material can be iron-doped indium phosphide, Fe:InP, wherein this material has a typical resistivity value of approximately 1×10⁷ ohm cm. Alternately the material can be Fe:InGaAsP or Fe:InGaAlAs, for example. In addition, materials having properties similar to those of Fe:InP can be used as the insulating or semi-insulating material. Other materials, which may be used for the basis of the semi-insulating material, can be based on the transition metals, such as cobalt, chromium and ruthenium.

In an alternate embodiment of the invention, wherein the p-substrate is of the form GaAs, the material used for the blocking layer can be Cr:GaAs. In addition, materials having properties similar to those of Cr:GaAs can be used as the insulating or semi-insulating material. Again, other materials, which may be used for the basis of the semi-insulating material, can be based on the transition metals, such as cobalt, chromium and ruthenium.

In an alternate embodiment of the invention the blocking layer can be formed from an alternative type of implanted material. For example, having regard to InP, implanting InP with atoms, like helium, gallium or protons can creates defects. These defects can trap carriers and thereby can stop current flow, thus producing a more insulating type of material.

In a further embodiment of the invention, another type of material for use as the blocking layer could be a material that readily oxidizes. For example, having regard to a material like AlInAs, since aluminum is contained in this alloy, AlInAs can oxidize easily and thus this oxidation of the blocking layer can result in an insulating quality thus limiting current flowing.

In yet another embodiment of the invention, the blocking layer may be formed by different fabrication processes and may comprises a variety of materials. For example, the blocking layer can comprise alternating layers of Fe:InP and n-InP or alternating layers of Fe:InP and p-InP. Another option may be for the blocking layers to be composed of a mixture of semi-insulating and implanted or oxidised materials, for example.

Second Series of Layers

Upon the completion of the deposition of the blocking layer, and the etching of the trench therein, with further reference to FIG. 5, a buffer layer 5 may be deposited in order to prevent direct contact between the blocking layer 4 and the subsequent n-clad layers 6, 7 and 8. The final layer 8, is deposited in order to provide a suitable interface with the n-side electrode. The essential portions of the second series of layers is to provide n-clad layers and a suitable interface for a n-side electrode on top of the final layer.

In one embodiment as illustrated in FIG. 6, wherein the waveguide laser structure is InP based, a buffer layer of n InP 50 is deposited on top of the blocking layer 40 and within the etched trench formed in the blocking layer 40. Then an InGaAsP layer 60 is deposited on top of this buffer layer 50. Subsequently, layers of n InP 70 and n+InGaAs 80 are deposited in order to provide a suitable interface with the n-side electrode. All these layers could include a plurality of layers but should be of n-type conductivity.

With further reference to FIG. 6, there are many potential variations to this waveguide semiconductor laser structure. For example the buffer layer 50 is not essential for device performance, but can be useful for the overgrowth step. In addition, the n+InGaAs layer 80 is also not essential, however this layer can be useful since it can provide a similar contact metallization technology that is currently in use for n-substrate lasers. And with further regard to layer 80 an alternate material providing essentially the same functionality is AlInGaAs. As would be readily appreciated by a worker skilled in the art, the active region is typically formed from InGaAsP materials and an alternate material composition for the active layer can be AlInGaAs.

In an alternate embodiment, the waveguide semiconductor laser can be based on a GaAs substrate wherein the second series of layers can include a series of layers of a n-conductivity type which are formed from material having a composition compatible with that of the GaAs substrate.

In general, the waveguide semiconductor laser may not be based on InP or GaAs. In this case the second series of layers comprises a set of layers of n-conductivity, where at least one layer has an index of refraction higher than the index of refraction of the blocking layers. Alternatively, the blocking layer material can have a lower refractive index. For example, oxidised AlInAs would have a lower index of refraction than InP. In that case, layers 6 and 60 would not be needed and the local effective index in the blocking layers would be depressed instead of being increased in the trench region.

Fabrication

In one embodiment of the invention, the semiconductor structure of the waveguide semiconductor laser according to the present invention, can be fabricated by the following process:

With further reference to FIG. 6, first a p-InP clad layer, 20 is grown on a p-InP substrate 10. An active layer 30 is then grown, followed by a semi-insulating InP blocking layer 40 to form a multilayered structure. A dielectric layer for use as the etching mask, such as SiO₂ is deposited on top of the multilayered structure. The etching mask can be prepared by a photolithography technique to cover the required blocking area 40 of the multilayered structure and the semi-insulating layer is etched down to the active region to produce a trench. After removing the etching mask, an n-InP buffer layer 50, an n-InGaAsP guiding layer 60, another n-InP layer 70, and an n-InGaAs contact layer 80 are sequentially grown onto the substrate. Finally an n-side electrode and a p-side electrode are formed respectively on the upper surface of the multilayered structure and the lower surface of the substrate.

During the fabrication process the method of assembly follows the standard processes for the growth of semiconductor layers, including such processes as epitaxial growth of semiconductor layers, photolithography, dielectric and metal deposition, adhesion, thermal cycling, cleaning etc., which would be used during the preparation of the trench etch and the p- and n-contacts.

In this functional description, one should understand that a layer could comprise in reality a composition of several layers. In particular, the active region could comprise a single quantum well structure or a multi-quantum well structure.

Performance

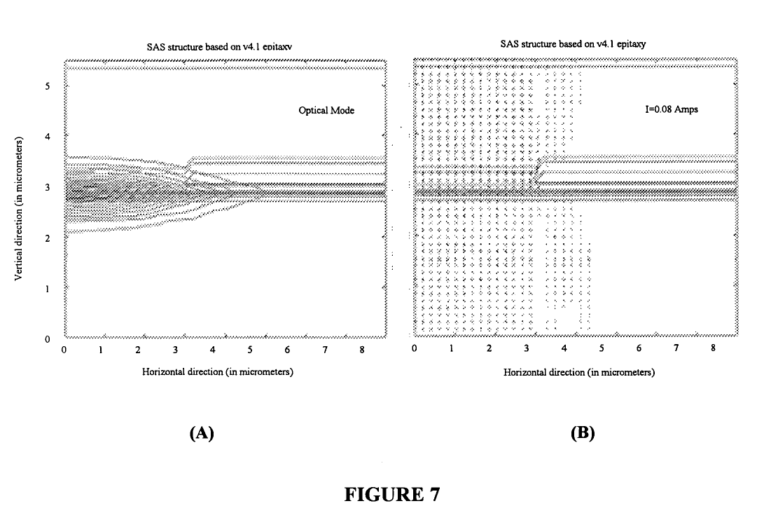

Having regard to FIG. 7A, theoretical values of the optical mode in a semiconductor laser structure designed according to one embodiment of the present invention, are illustrated graphically. This illustration presents the optical mode for half of the semiconductor laser structure, wherein this response would be symmetrical on the other side of the structure. One is able to see that the optical signal is concentrated within the trench that has been formed within the blocking layer.

In addition, having regard to FIG. 7B, theoretical values of the current flow in a semiconductor laser structure designed according to one embodiment of the present invention, are illustrated graphically. This illustration presents the current level for half of the semiconductor laser structure, wherein these levels would be symmetrical on the other side of the structure. One is able to see that the current level is concentrated within the trench that has been formed within the blocking layer and that very little of the current is leaking laterally. Therefore, control of the current can be provided with low leakage, indicating the efficacy of the blocking layer as provided by the present invention.

In one embodiment an advantage of the present invention is that it does not require etching through the active region, wherein this fact can prevent any distortion or change to this active region during the etching process. In addition, the etching of the blocking layer is a simple and self-aligned process and allows choice of a high-bandgap material (i.e. InP) that can result in improved performance of the device under high current injection and high temperature, for example.

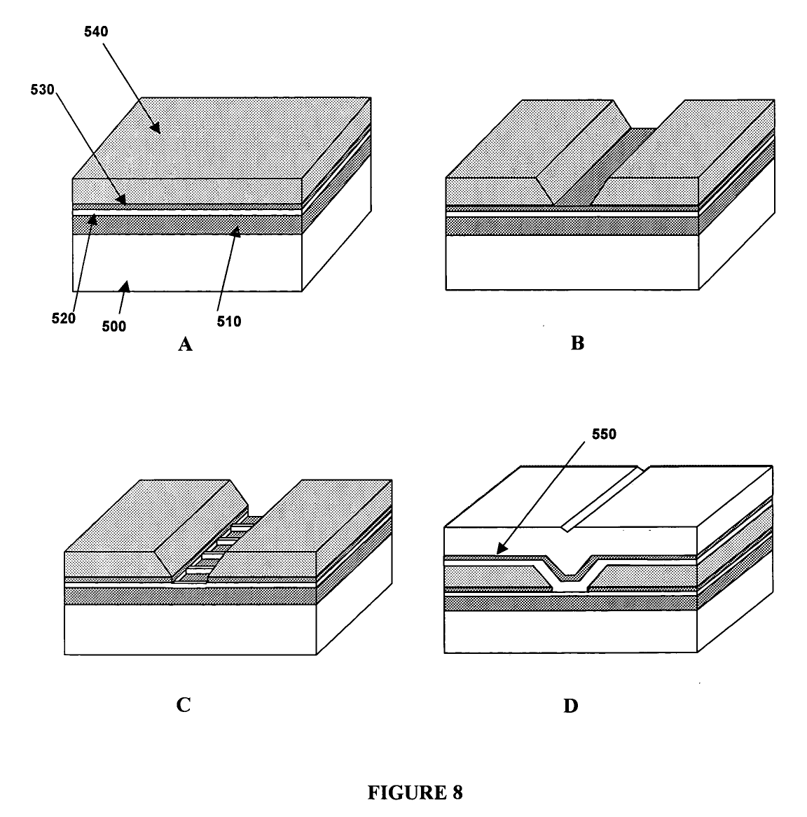

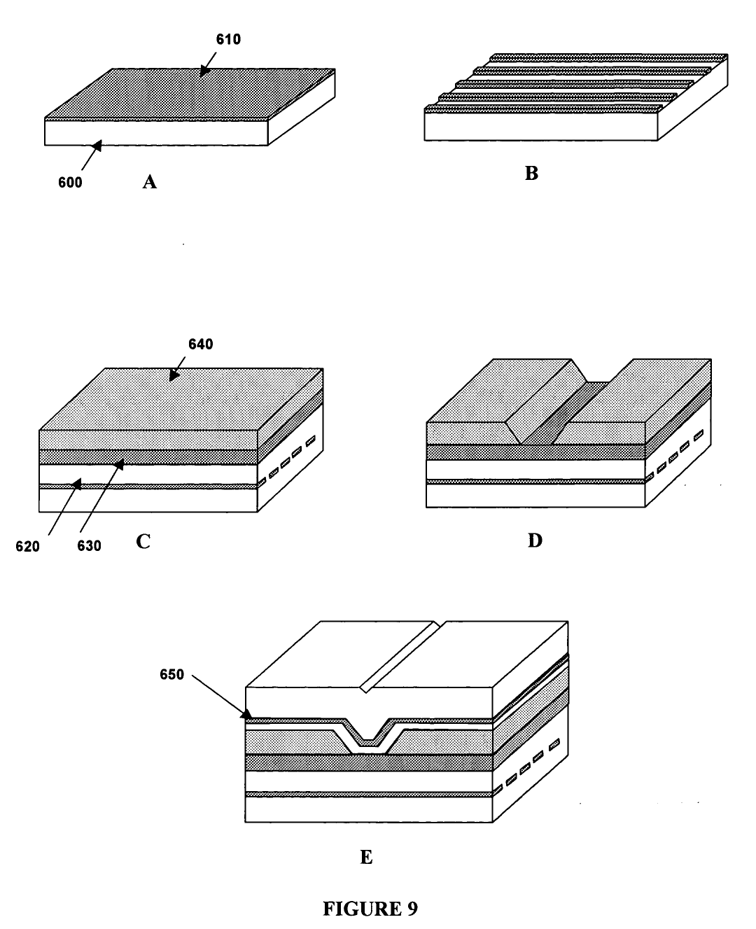

The present invention can also be applied to other types of laser devices including structures that require gratings, for example a DFB (distributed feedback) laser, DBR (Distributed Bragg reflector), filters and other semiconductor structures which can be used in telecom applications as signal lasers. FIGS. 8 and 9 illustrate embodiments of the invention associated with a DFB laser wherein FIG. 8 illustrates a partly gain-coupled DFB laser and FIG. 9 illustrates an index-coupled DFB laser.

FIG. 8 illustrates one embodiment of the invention as associated with a partly gain-coupled DFB laser. FIG. 8A shows the first series of growths including a p-InP 500, an active layer 510, an InGaAsP layer 520 into which the grating will be etched and this layer forms part of the active region thereby producing the partly gain-coupling in the device, an etch stop layer 530 and a blocking layer 540 formed from Fe:InP. FIG. 8B shows the etching of the trench into the blocking layer down to the etch-stop layer. FIG. 8C shows the grating etch, in which the etch-stop layer is removed and the grating layer is created by etching away the areas between the grating lines of the InGaAsP layer 520. FIG. 8D shows the final growth to of the buffer layer, guiding layer 550 formed from p-InGaAsP and the contact layer, thereby forming a partly gain-coupled DFB laser according to the present invention.

FIG. 9 illustrates an embodiment of the present invention as associated with an index-coupled DFB laser, where the grating is separated from the active layer. FIG. 9A shows the first growth of the p-InGaAsP grating material 610 onto the p-InP base material 600. FIG. 9B shows the required grating structure etched into the p-InGaAsP layer 610. FIG. 9C shows the deposition of another p-InP layer 630, the active layer 630 and the Fe:InP blocking layer 640. FIG. 9D shows the formation of the trench in the blocking layer 640 by etching away the central section. FIG. 9E shows the final structure after overgrowth including a buffer layer, guide layer 650 of p-InGaAsP and a contact layer, thereby forming an index coupled DFB laser according to the present invention.

There may be changes within the layers of the semiconductor structure as defined above wherein these changes can ease the fabrication processes without altering the principle of the present invention. For example additional layers may be added to allow for alternative methods of construction. For example a very thin layer of material may be inserted between the blocking layer and the active region. This thin layer could be composed of p-InP, with the trench being etched in the blocking layer and the p-InP down to the active region. Other minor options are also possible.

The embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor laser structure, based on p-substrate materials, said structure including a plurality of layers, each layer including one or more sublayers, said structure comprising:
a) a first layer forming a p-clad layer, said first layer having a bottom surface;
b) a second layer being an active layer deposited on the first layer;
c) a third layer being a blocking layer formed from an insulating or semi-insulating material, said blocking layer including two parts aligned with a gap therebetween, said gap and said blocking layer having dimensions selected to meet a desired response of the semiconductor laser structure, said blocking layer deposited on the active layer; and
d) a fourth layer forming a n-clad layer, said fourth layer having a top surface, said fourth layer deposited on the third layer;
wherein a negative electrode is formed on the top surface and a positive electrode is formed of the bottom surface.

2. A semiconductor laser structure according to claim 1, where said p-substrate material is a p-InP substrate material, wherein said n-clad layer and p-clad layer are compatible with an InP material system.

3. A semiconductor laser structure according to claim 1, where said p-substrate material is a p-GaAs substrate material, wherein the n-clad layer and the p-clad layer are compatible with a GaAs material system.

4. A semiconductor laser structure according to claim 2, wherein said third layer is a Fe:InP layer.

5. A semiconductor laser structure according to claim 2, wherein said third layer is a Fe:InGaAsP layer.

6. A semiconductor laser structure according to claim 2, wherein said third layer is a Fe:InGaAlAs layer.

7. A semiconductor laser structure according to claim 3, wherein said third layer is a Cr:GaAs layer.

8. A semiconductor laser structure according to claim 2 wherein said third layer is formed from a material having properties similar to Fe:InP.

9. A semiconductor laser structure according to claim 3 wherein said third layer is formed from a material having properties similar to Cr:GaAs.

10. A semiconductor laser structure according to claim 1 wherein said third layer is formed from an implanted semiconductor material.

11. A semiconductor laser structure according to claim 1 wherein said third layer is formed from a semiconductor material that oxidizes.

12. A semiconductor laser structure according to claim 1 where one of the layers comprises a grating.

13. A semiconductor laser structure, based on p-substrate materials, said structure including a plurality of layers, each layer including one or more sublayers, said structure comprising:
a) a first layer, said first layer comprising a p-InP substrate, said first layer having a bottom surface;
b) a second layer deposited on the first layer, said second layer being an active layer;
c) a third layer deposited on the second layer, said third layer being a blocking layer comprising an insulating or semi-insulating material, said third layer including two parts, aligned with a gap therebetween, said gap having dimensions selected to meet a required specific response of the structure;
d) a fourth layer deposited on the third layer, said fourth layer comprising a n-InGaAsP layer; and
e) a fifth layer deposited on the fourth layer, said fifth layer being a cladding layer comprising a n-InP layer and said fifth layer having a top surface;
wherein a negative electrode is formed on the top surface and a positive electrode is formed of the bottom surface.

14. A semiconductor laser structure according to claim 13, where said first layer further comprises a p-InP layer deposited on the n-InP substrate.

15. A semiconductor laser structure according to claim 13, where said fourth layer further comprises a n-InP layer deposited prior to the n-InGaAsP layer.

16. A semiconductor laser structure according to claim 13, where the fifth layer further comprises a n-InGaAs layer deposited on the top of the n-InP layer.

17. A semiconductor laser structure according to claim 13, wherein said second active layer contains a single quantum well structure.

18. A semiconductor laser structure according to claim 13, wherein said second active layer contains a multi-quantum well structure.

19. A semiconductor laser structure according to claim 13, wherein said third layer is a Fe:InP layer.

20. A semiconductor laser structure according to claim 13, wherein said third layer is a Fe:InGaAsP layer.

21. A semiconductor laser structure according to claim 13, wherein said third layer is a Fe:InGaAlAs layer.

22. A semiconductor laser structure according to claim 13 wherein said third layer is formed from a material having properties similar to Fe:InP.

23. A semiconductor laser structure according to claim 13 wherein said third layer is formed from an implanted semiconductor material.

24. A semiconductor laser structure according to claim 13 wherein said third layer is formed from a semiconductor material that oxidizes.

25. A semiconductor laser structure according to claim 13 where one of the layers comprises a grating.

26. A semiconductor laser structure according to claim 1, where said p-substrate material is a p-GaN substrate material, wherein the n-clad layer and the p-clad layer are compatible with a GaN material system.
